(19) United States
(12) Patent Application Publication
(10) Pub. No.: US 2025/0351382 A1
(43) Pub. Date: Nov. 13, 2025

(54) HIGH BANDWIDTH MEMORY SYSTEM-IN-PACKAGE INTEGRATION BRINGU

(71) Applicant: Micron Technology, Inc., Boise, ID (US)

(72) Inventors: Rajesh Hariram Kariya, Boise, ID (US); Joon Sik Sohn Lee, Meridian, ID (US)

(21) Appl. No.: 19/197,421

(22) Filed: May 2, 2025

Related U.S. Application Data
(60) Provisional application No. 63/643,694, filed on May 7, 2024.
(60) Provisional application No. 63/664,387, filed on Jun. 26, 2024.

(51) Int. Cl. H10B 80/00; H01L 21/66; H01L 23/522; H01L 25/00; H01L 25/065; H01L 25/18

(52) U.S. Cl. CPC H10B 80/00; H01L 22/12; H01L 22/34; H01L 23/5221; H01L 25/0657; H01L 25/18; H01L 25/50; H01L 2225/06541; H01L 2225/06596

(57) ABSTRACT

Systems and methods related to testing of designs for system-in-packages (SiP) comprising high-bandwidth memory (HBM) and system on a chip (SOC) devices are discussed herein. Live HBM devices may be used in combination with a silicon bridge to form a proxy SiP device. The silicon bridge has the same size and shape as the SOC that it replaces. The differences in electrical properties between the proxy and the actual SiP are reduced by using the silicon bridge instead of connecting the HBMs through the substrate. By comparison with using a live SOC, using the silicon bridge reduces the cost of producing the proxy. An external testing device may be coupled to access pins of the proxy SiP device and execute one or more tests.

### PRIORITY APPLICATION

This application claims the benefit of priority to U.S. Provisional Application Ser. No. 63/664,387, filed Jun. 26, 2024, and to U.S. Provisional Application Ser. No. 63/643,694, filed May 7, 2024, all of which are incorporated herein by reference in their entirety.

### TECHNICAL FIELD

The present disclosure generally relates to integration of high-bandwidth memory (HBM) devices and, more specifically, to HBM system-in-package (SiP) bringup.

### BACKGROUND

Complex devices are formed by integrating multiple circuit designs into a single package. Real devices differ from theoretical performance. Accordingly, designs may be modified in an iterative process as fabricated devices are tested. Vertical interconnect accesses (VIAs) introduce three-dimensional circuits and have an impact on resistive, capacitive, and inductive properties. Daisy-chain test vehicles (DCTVs) contain strings of interconnected through-silicon VIAs (TSVs). One or more components of a complex device may be replaced with a DCTV. The resulting device may be used to learn approximations of the electrical properties of real components.

### BRIEF DESCRIPTION OF THE DRAWINGS

The present disclosure will be understood more fully from the detailed description given below and from the accompanying drawings of various embodiments of the disclosure.

FIG. 1 illustrates an example SiP that includes an HBM DCTV and a system-on-a-chip (SOC) DCTV in accordance with some embodiments of the present disclosure.

FIG. 2 illustrates an example SiP that includes two HBMs in accordance with some embodiments of the present disclosure.

FIG. 3 illustrates a top view of an example SiP that includes four HBMs and an SOC, in accordance with some embodiments of the present disclosure.

FIG. 4 illustrates a side view of the example SiP of FIG. 3.

FIG. 5 illustrates a top view of an example SiP that includes four HBMs, in accordance with some embodiments of the present disclosure.

FIG. 6 illustrates a side view of the example SiP of FIG. 5.

FIG. 7 illustrates a top view of an example SiP that includes four HBMs and silicon acting as a metal bridge, in accordance with some embodiments of the present disclosure.

FIG. 8 illustrates a side view of the example SiP of FIG. 7.

FIG. 9 is a partially schematic cross-sectional view of an environment configured in accordance with some embodiments of the present disclosure.

FIG. 10 is a partially schematic top view of the environment of FIG. 9.

FIG. 11 illustrates a flowchart of a method for testing a SiP, according to some example embodiments.

FIG. 12 illustrates a flowchart of a method for testing a SiP, according to some example embodiments.

FIG. 13 is a block diagram of an example computer system in which embodiments of the present disclosure may operate.

### DETAILED DESCRIPTION

Aspects of the present disclosure are directed to an improved SiP for testing integration of components in a package. One or more components of the package are used in the SiP and one or more components of the package are replaced with silicon of the same size and shape as the replaced component (referred to as a “silicon bridge”). The silicon bridge includes one or more conductive paths, allowing electrical conductivity through the silicon bridge. The silicon bridge provides structural properties similar to the component that the silicon bridge is designed or configured to replace.

The present inventors have recognized that it can be advantageous to test aspects of an SiP before all of the final components of the package are available. The improved SiP devices and systems discussed herein, which can include or use a silicon bridge, can help enable early testing of SiPs. The silicon bridge may be fabricated while the component it is configured to replace is still in the design phase and has not yet been fabricated, allowing other components to be tested for integration into the package even though not all final components are available. In some examples, the silicon bridge may be fabricated using a more accessible (e.g., less expensive, more efficient, etc.) process than is used for the corresponding final component that the silicon bridge is configured to replace. For example, the silicon bridge may be fabricated using a 14 nanometer (nm) process while the corresponding final component is fabricated using a 5 nm process. Though referred to as a silicon bridge, other semiconductors could be used in place of silicon, such as cubic boron arsenide, germanium, graphene, gallium nitride, gallium arsenide, silicon carbide, and the like.

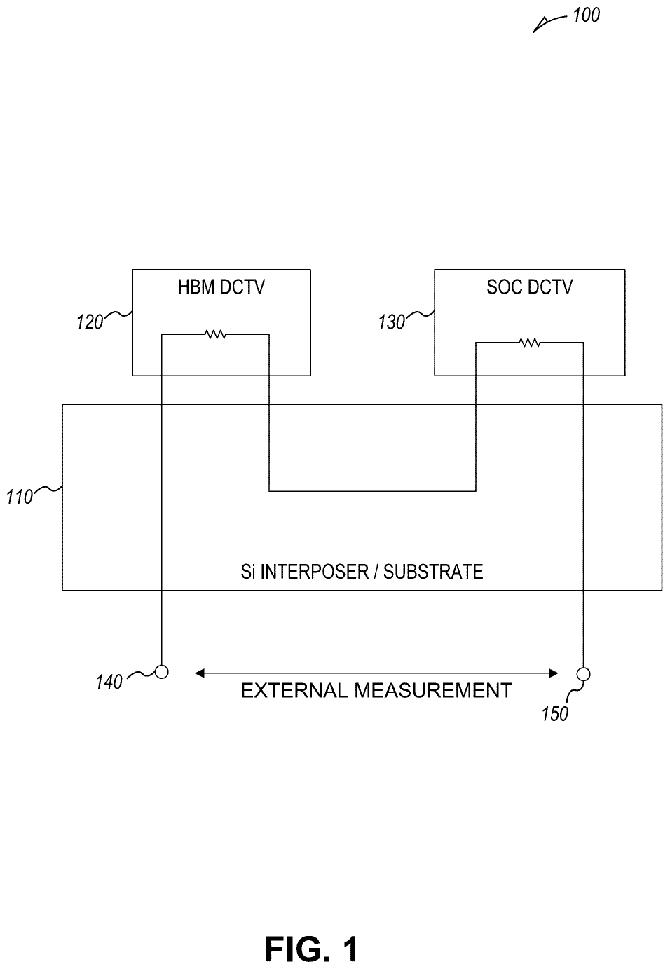

FIG. 1 illustrates an example SiP 100 that includes an HBM DCTV 120 and a system-on-a-chip (SOC) DCTV 130 in accordance with some embodiments of the present disclosure. Since the SiP 100 includes no live components and instead uses DCTVs to replace them, the SiP 100 may be referred to as a DCTV SiP. To approximate the resistance of the integrated package, the HBM DCTV 120 and the SOC DCTV 130 are placed on a substrate 110. The resistance between two external connections 140 and 150 is measured. The electrical connection between the two external connections 140 and 150 passes through the substrate 110, the HBM DCTV 120, and the SOC DCTV 130. Mechanical stress for the DCTV SiP may also be measured.

However, DCTV warpage and mechanical properties may be considerably different from the product being simulated since DCTV lacks front-end-of-line (FEOL) and middle-of-line (MOL) layers. Also, a DCTV SiP does not allow alternating current (AC) characterization of the device. DCTV design and fabrication also take additional time before testing can be performed.

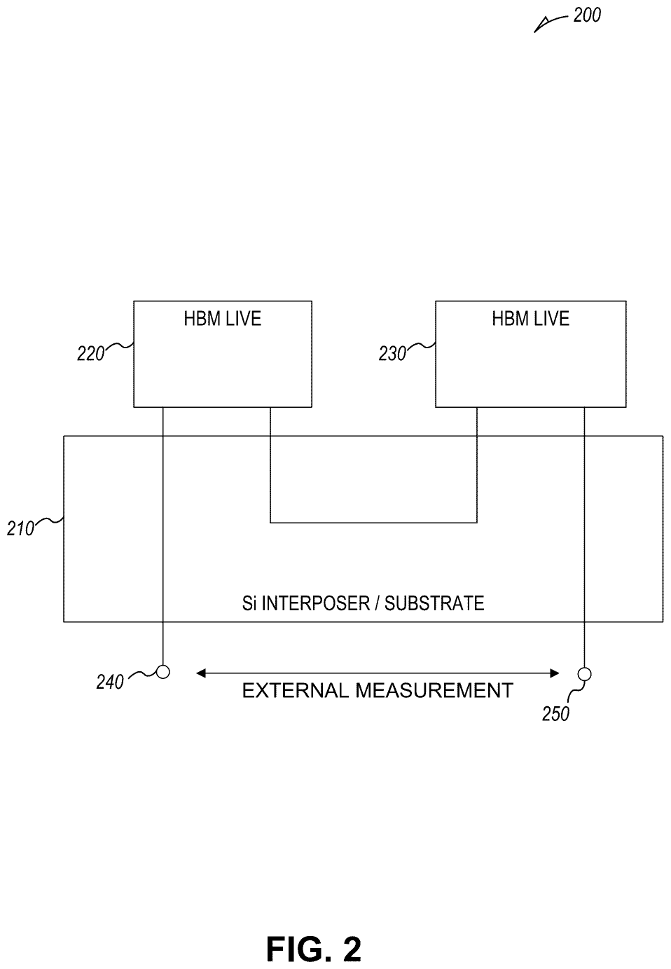

FIG. 2 illustrates an example SiP 200 that includes two HBMs 220 and 230 in accordance with some embodiments of the present disclosure. The HBMs 220 and 230 are placed on a substrate 210. Signals may be provided to one or both of the HBMs 220-230, received from one or both of the HBMs 220-230, or both, via the external connections 240 and 250. The SiP 200 and the SiP 100 are SiPs for the same product, comprising an HBM and an SOC.

In the example of FIG. 2, the SOC (previously replaced by the SOC DCTV 130) is replaced by the HBM 230. The two HBMs 220 and 230 can communicate with each other (e.g., by running read and write diagnostics). Since no HBM DCTV is used in the SiP 200, a DCTV for the HBM does not need to be designed. Since the SOC is not used at all (either in live or DCTV form), the physical layout of the SiP 200 can be tested before the SOC is ready. Since the HBMs 220 and 230 are operating chips, AC characteristics of the SiP 200 can be tested in addition to the tests that can be run on the DCTV SiP 100 of FIG. 1. The tests may include, for example, direct current (DC) connectivity tests, AC tests controlled by a multiple input signature register (MISR) using direct access (DA) pins, assuming termination and routing study, or die crack/edge die monitor tests, among others.

By comparison with the DCTV SiP 100 of FIG. 1, the SiP 200 of FIG. 2 eliminates the need for design and fabrication of the DCTV silicon and cube integration. Additionally, since the HBMs 220 and 230 include FEOL and MOL, warpage and mechanical properties are a true representation of the final HBM product.

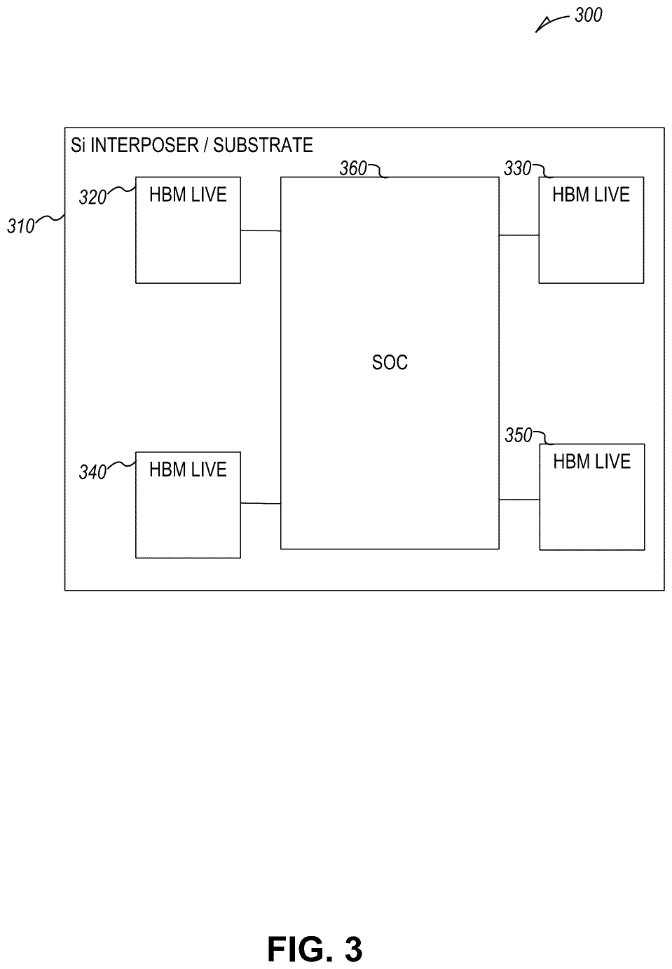

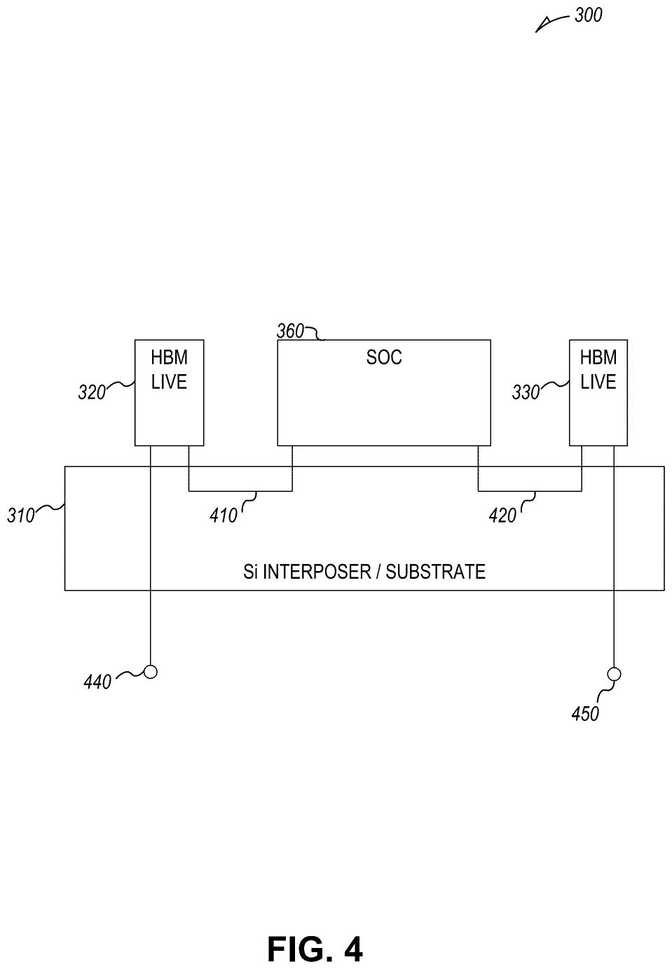

FIG. 3 illustrates a top view of an example SiP 300 that includes four HBMs 320, 330, 340, and 350 and an SOC 360, in accordance with some embodiments of the present disclosure. FIG. 4 illustrates a side view of the example SiP 300 of FIG. 3. The HBMs 320-350 and the SOC 360 are integrated with a substrate 310. As can be seen in FIG. 4, external connections 440 and 450 are connected to the HBMs 320 and 330, respectively. Only a few external connections are shown, but many such external connections (e.g., in the form of pins with metal balls) may be present. The SOC 360 is connected, via native channels in the substrate 310 (e.g., the native channels 410 and 420), to the four HBMs 320-350. The SiP 300 is a live device that can be tested for full functionality of the integration of the SOC 360 with the HBMs 320-350. However, the SiP 300 cannot be fabricated unless all components are ready.

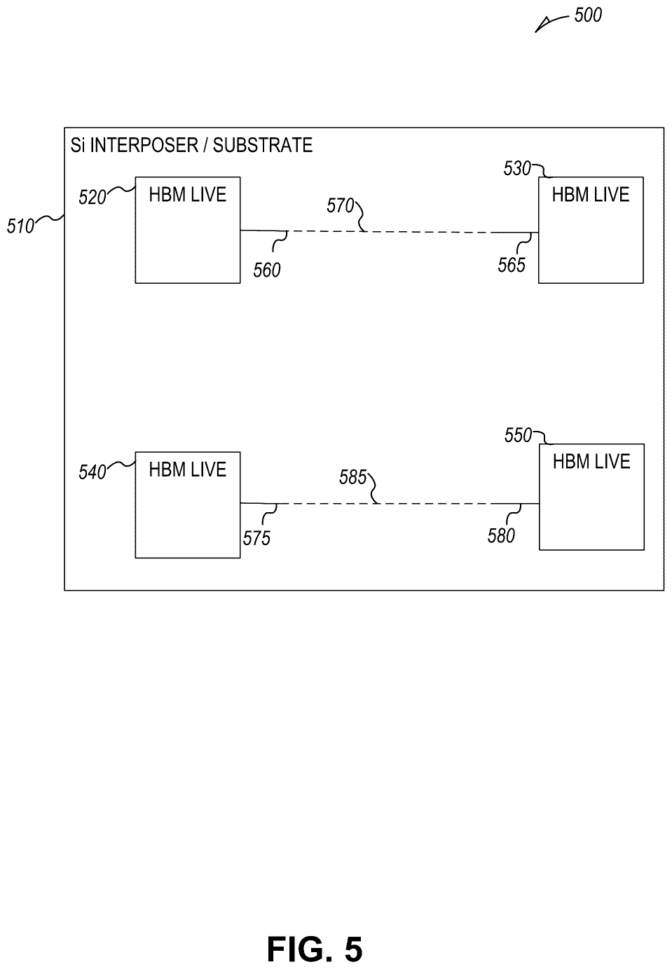

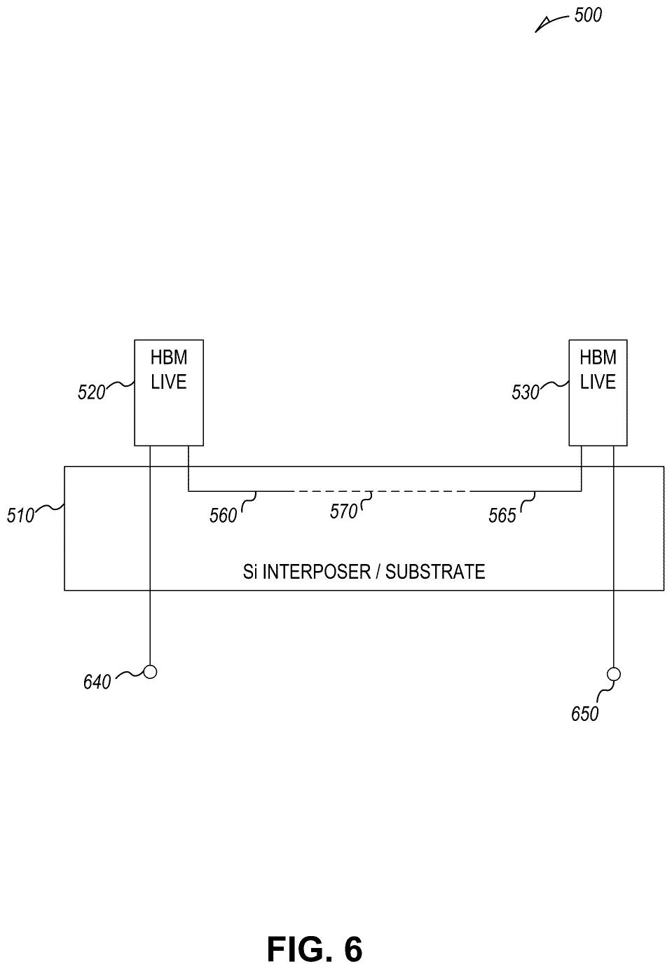

FIG. 5 illustrates a top view of an example SiP 500 that includes four HBMs 520, 530, 540, and 550, in accordance with some embodiments of the present disclosure. FIG. 6 illustrates a side view of the example SiP 500 of FIG. 5. Unlike the SiP 300 of FIGS. 3-4, the SiP 500 does not include an SOC. The SiP 500 includes four HBMs 520, 530, 540, and 550, on a substrate 510. As shown in FIG. 6, the HBMs 520 and 530 are connected to direct access pins 640 and 650, respectively.

As with the SiP 300 of FIGS. 3-4, the SiP 500 includes native channels in the substrate 510. These native channels 560, 565, 575, and 580 are conductive paths in the substrate 510 that are part of the package design. Additionally, routing 570 and 585 are added to the substrate 510, allowing the HBMs 520 and 530 to communicate and allowing the HBMs 540 and 550 to communicate.

Thus, the SiP 500 can be tested with the HBMs 520-550 in place, with the benefits discussed with respect to FIG. 2. However, adding the routing 570 and 585 between the HBM pairs 520-530 and 540-550 requires redesign of the silicon interposer/substrate 510. Additionally, the design of FIGS. 5-6 will not accurately reflect the impact of the SOC on warpage or stress of the package.

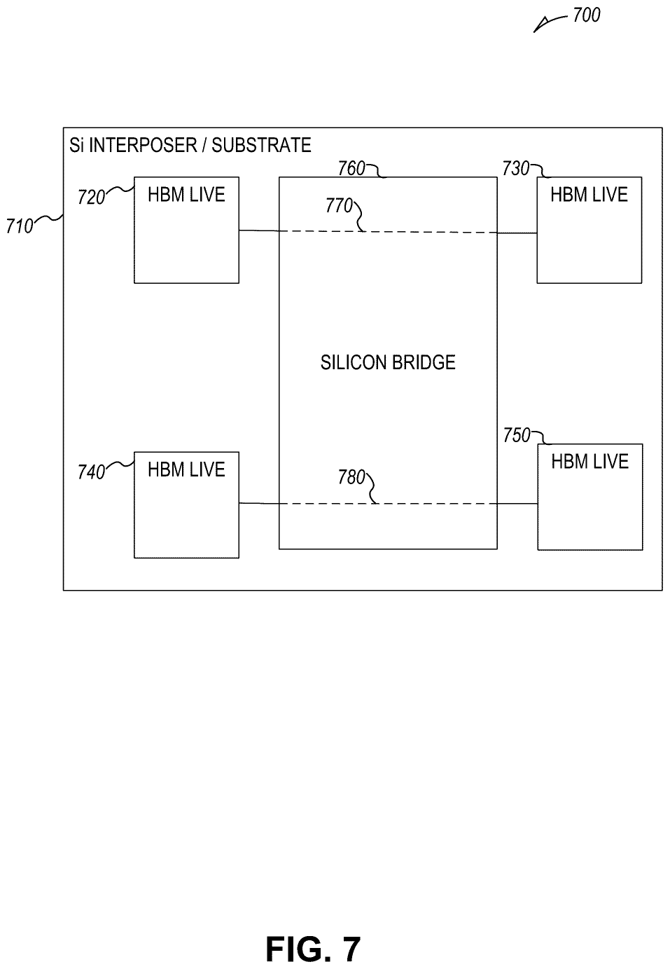

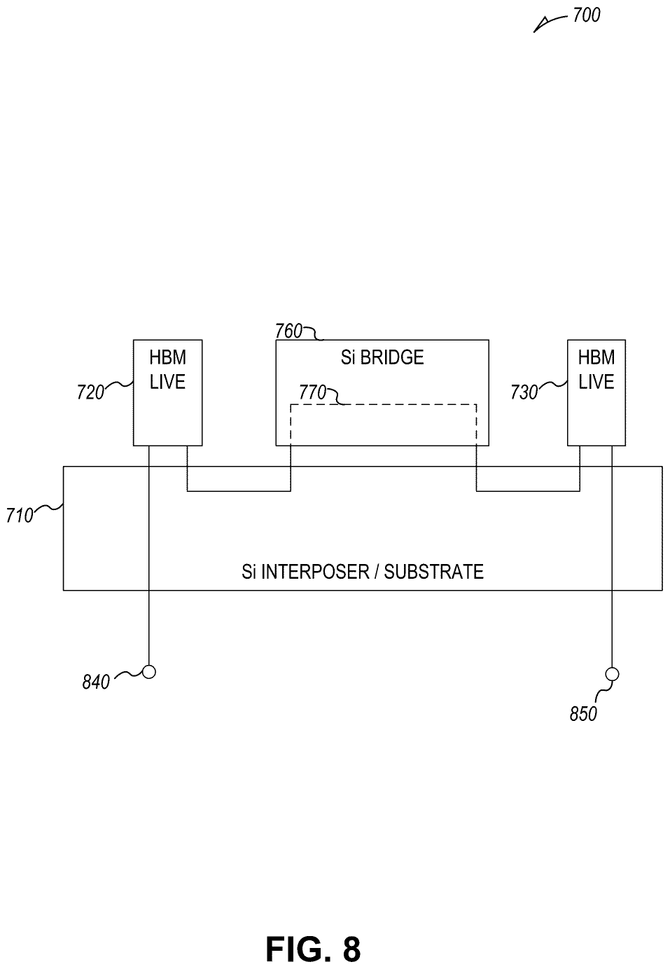

FIGS. 7 and 8 show top and side views of a SiP 700 that is similar to the SiP 300 of FIGS. 3-4 with the SOC 360 replaced by silicon acting as a metal bridge 760. The SiP 700 includes a substrate 710; HBMs 720, 730, 740, and 750; and the silicon acting as a metal bridge 760. As shown in FIG. 8, the HBMs 720 and 730 are connected to direct access pins 840 and 850, respectively.

The native channels through the silicon interposer/substrate 710 are the same as those used for the SiP 300 of FIGS. 3-4. Accordingly, no redesign of the SiP is needed. The additional silicon acting as a metal bridge 760 is created with the same size and shape as the SOC 360 it substitutes for. As a result, the warpage and stress characteristics of the SiP 700 of FIGS. 7-8 are very similar to those of the SiP 300 of FIGS. 3-4. The silicon acting as a metal bridge 760 includes conductors 770 and 780 to pairwise connect the HBMs 720, 730 and 740, 750 to allow for communications.

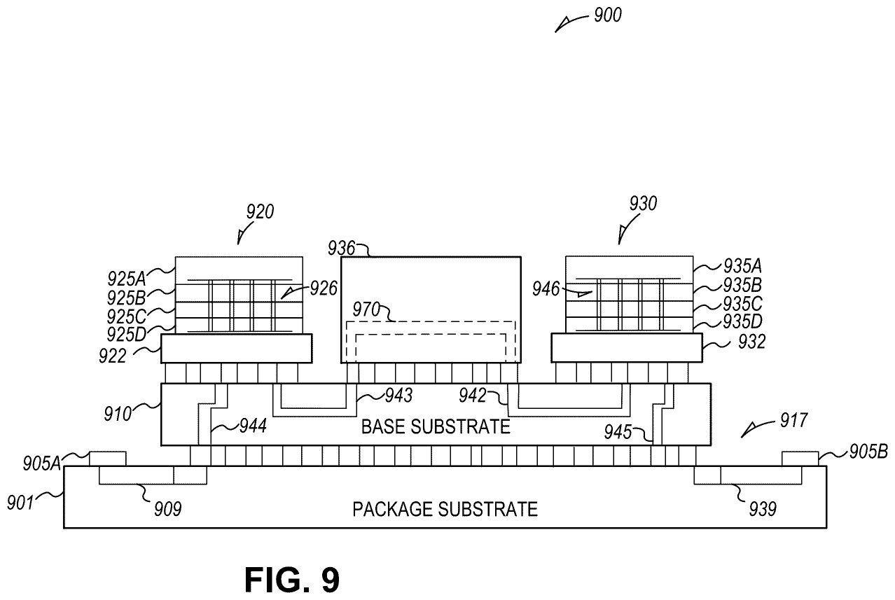

FIG. 9 is a schematic cross-sectional view of an environment 900 configured in accordance with various embodiments of the present technology. As shown, the environment 900 includes a proxy device integrated with a package substrate 901 (e.g., a PCB or another suitable substrate). The proxy device (sometimes also referred to herein as a “SiP proxy device,” a “SiP device,” a “device,” and/or the like) includes a first HBM 920, a second HBM 930, and a silicon bridge 936, each of which is integrated with a base substrate 910 (e.g., a silicon interposer, a substrate of organic material, a substrate of inorganic material, and/or any other suitable material), such as at an upper surface of the base substrate 910.

In the illustrated embodiment, the first HBM 920 includes a base die 922 (e.g., an interface die or other suitable substrate); a stack of memory dies 925A, 925B, 925C, and 925D (e.g., DRAM dies and/or another suitable type of memory die) carried by the base die 922; and TSVs 926 extending between the base die 922 and each of the memory dies 925A-925D in the stack. The second HBM 930 is similarly structured and includes a base die 932; a stack of memory dies 935A, 935B, 935C, and 935D carried by the base die 932; and TSVs 946 extending between the base die 932 and each of the memory dies 935A-935D in the stack.

In some embodiments, the first HBM 920 and/or the second HBM 930 can include circuits and/or active components (e.g., FEOL and/or MOL layers forming memory circuits/components, physical layers (PHYs), and/or various other suitable circuits/components) in the base dies 922 and 932 and/or in one or more of the memory dies 925A-925D and 935A-935D. Accordingly, each of the first and second HBMs 920 and 930 may include a stack of substrates, wherein at least one substrate in each stack includes FEOL layers, MOL layers, or both. As a specific example, as discussed in greater detail below, the first HBM 920 and/or the second HBM 930 can be HBM devices with minimum basic functionality (e.g., HBM devices that have been identified as functional rejects and/or that have been rejected during quality control or other testing from being implemented into customer products, but that have at least minimum basic functionality useful for conducting one or more tests included in SiP integration bringup processes of the present technology). Whether fully functional or not, the first HBM 920 and/or the second HBM 930 therefore include compositions, mechanical properties, and/or other characteristics identical (or at least generally similar) to a fully functioning HBM device. Thus, in such an example, the first HBM 920 and/or the second HBM 930 are expected to provide a better (e.g., more true, more accurate) representation of the fully functioning HBM device than a DCTV.

As further illustrated in FIG. 9, the base substrate 910 can include one or more communication channels 942 and 943, one or more interconnects 944 and 945, and can be mounted to the silicon bridge 936. The silicon bridge 936 is not drawn to scale and is the size and shape of an SOC to be used in the SiP that is being proxied in FIG. 9. The silicon bridge 936 includes the communication channels 970. The communication channels 942, 943, and 970 communicably couple the first HBM 920 to the second HBM 930 and pass through both the base substrate 910 and the silicon bridge 936. The interconnects 944 couple the first HBM 920 to external interconnects 917 (e.g., solder structures, metal pads, and/or any other suitable structure) at a lower surface of the base substrate 910. The interconnects 945 couple the second HBM 930 to the external interconnects 917. In turn, the external interconnects 917 can be coupled to one or more access pins 905A or 905B of the package substrate 901, such as via route lines or interconnects 909 and 939 in the package substrate 901. As such, the first HBM 920 and the second HBM 930 can each be communicably coupled to at least one of the access pins 905A and 905B. In some embodiments, the access pins 905A and 905B can be direct access pins or direct access external balls of or on the package substrate 901. As discussed in greater detail below, the access pins 905A and 905B can be coupled to an external testing device (e.g., a tester, an external controller). Therefore, the external testing device can communicate with (e.g., access, control, send signals to, receive signals from) the first HBM 920 and/or the second HBM 930 via at least one of the access pins 905A and 905B to, for example, implement one or more tests (e.g., DC signal tests, AC signal tests, die crack tests, and/or the like) during an SiP integration bringup process.

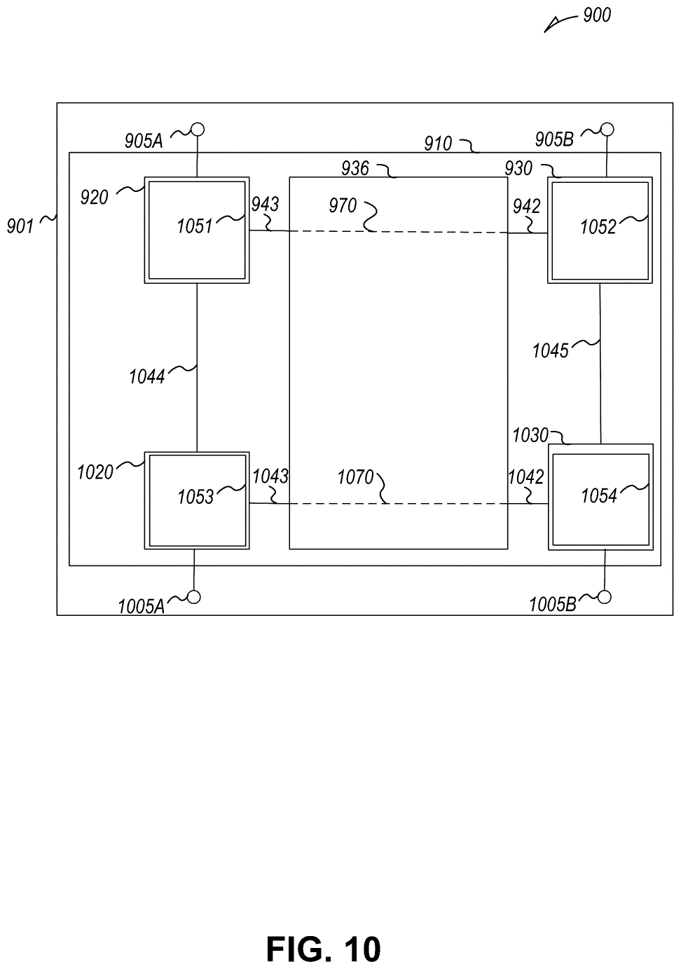

Purely by way of example, the first HBM 920 can be instructed (e.g., by an external testing device coupled to two or more of the access pins 905A and 905B and 1005A and 1005B of FIG. 10) to communicate a DC signal to the second HBM 930 via the communication channels 942, 943, and 970. The DC signal can then be read out from the second HBM 930 (e.g., by the external testing device and/or via one of the access pins 905A and 905B and 1005A and 1005B) to determine whether the correct signal was received (and/or whether any signal was received). If the correct signal was not received or if no signal was received, this can indicate that there is a bad connection within the first HBM 920, within the second HBM 930, within the communication channels 942, 943, and/or 970, and/or within the interconnects 917, 944, 945, 909, and/or 939, and/or between the first and second HBMs 920 and 930 and the access pins 905A and 905B. The bad connection, in turn, indicates a lack of compatibility between the first HBM 920, the second HBM 930, the base substrate 910, the proxy device, the package substrate 901, the silicon bridge 936, and/or the packaging process(es) used to integrate these components with one another.

FIG. 10 is a schematic top view of the environment 900 of FIG. 9. As shown, the proxy device can include HBMs 1020 and 1030 in addition to the first HBM 920 and the second HBM 930 described above with reference to FIG. 9. Although shown with four HBMs 920-930 and 1020-1030 in the illustrated embodiment, the proxy device can include a different number of HBMs (e.g., one, two, three, or more than four HBMs) in other embodiments of the present technology.

In the illustrated embodiment, the HBMs 920-930 and 1020-1030 are positioned around a central region of the base substrate 910. The central region (sometimes also referred to herein as a “central portion,” a “host-connecting portion,” and/or the like) can be integrated with the silicon bridge 936. In such embodiments, the silicon bridge 936 can be integrated with the base substrate 910. Including the silicon bridge 936 may provide a better (e.g., more true, more accurate) representation of warpage and/or other responses of various components of a SiP device resembled by the proxy device and/or of the package substrate 901. In other words, including the silicon bridge 936 may provide a better assessment or characterization of compatibility between various components of the proxy device (and/or of components of a SiP device simulated by the proxy device), the package substrate 901, and/or packaging processes used to integrate these components with one another.

As further illustrated in FIG. 10, similar to the first HBM 920 and the second HBM 930 described above with reference to FIG. 9, the third HBM 1020 and the fourth HBM 1030 can be communicably coupled to one another via communication channels 1042 and 1043 in the base substrate 910 and communication channel 1070 in the silicon bridge 936. Additionally, or alternatively, the third HBM 1020 can be communicably coupled to the first HBM 920 via communication channel 1044 in the base substrate 910, and/or the fourth HBM 1030 can be communicably coupled to the second HBM 930 via communication channel 1045 in the base substrate 910. Continuing with the illustrated example, the first and second HBMs 920 and 930 can form a first pair; the third and fourth HBMs 1020 and 1030 can form a second pair; the first and third HBMs 920, 1020 can form a third pair; and the second and fourth HBMs 930, 1030 can form a fourth pair.

Further, each of the HBMs 920, 930, 1020, and 1030 can be coupled to one of the access pins 905A, 905B, 1005A, or 1005B on the package substrate 901. As a result, each of the pairs (or any subset thereof) can be used (e.g., by an external testing device coupled to one or more of the access pins 905A-905B and 1005A-1005B) to implement various tests, such as during a SiP integration bringup process. In some embodiments, executing a SiP integration bringup process includes executing duplicative tests with the pairs (e.g., multiple DC signal tests to evaluate how many bad connections, if any, exist in the environment 900 and/or to attempt to identify where in the environment 900 a connectivity issue is located). As a specific example, a first DC connectivity test can be performed using the first HBM 920 and the second HBM 930. If a connectivity issue is identified during the first test, a second DC connectivity test can be performed using the first HBM 920 and the third HBM 1020 to, for example, determine whether the connectivity issue is likely located within the first HBM 920 or another portion of the communication paths common to both the first and second tests. Additional tests can be conducted (as needed) to determine a location of the connectivity issue. As another example, executing a SiP integration bringup process can include simultaneously implementing multiple tests using the pairs (e.g., using the first pair to implement a first test while using the second pair to implement a second test). Thus, in some example embodiments, executing one or more tests on the SiP includes executing a first subset of the one or more tests on the first and second HBMs 920 and 930 and a second subset of the one or more tests on the third and fourth HBMs 1020 and 1030.

As further illustrated in the embodiment of FIG. 10, each of the HBMs 920-930 and 1020-1030 can include one or more die crack monitors 1051, 1052, 1053, and 1054. In some embodiments, the die crack monitors 1051-1054 can be formed in the base dies 922 and 923 and/or in one or more of the memory dies 925A-925D and 935A-935D of the HBMs 920-930 and 1020-1030. The die crack monitors 1051-1054 (sometimes referred to as “die crack sensors”) can include a circuit that traces or extends about a perimeter of the corresponding die. The circuit (e.g., a metal route line and/or other suitable structure) of each of the die crack monitors 1051-1054 can include an input and an output. When a signal (e.g., a DC signal) is loaded onto the input, the signal can be read at the output to confirm that the circuit is intact. A crack in the corresponding die, however, may disrupt or break the circuit, resulting in losses in the signal and/or in breaking of the circuit altogether. Further, because the circuit traces or extends about a perimeter of the corresponding die, the die crack monitors 1051-1054 can detect a crack resulting from mechanical stresses/impacts before the crack damages other circuits in the corresponding die (e.g., transistors in the DRAM dies). For example, the die crack monitors 1051-1054 can detect mechanical damage that has not yet undermined the integrity of the dies in the HBM devices, but could propagate over time and reduce the lifetime of the resulting packaged device. Accordingly, the tests performed on the SiP can include checking, using a die crack sensor, for cracks resulting from integration of the device with the package substrate.

In some embodiments, one or more of the HBMs 920-930 and 1020-1030 include a plurality of the die crack monitors 1051-1054 (e.g., one on each die therein). In some embodiments, one or more of the HBMs 920-930 and 1020-1030 include a single one of the die crack monitors 1051-1054 (e.g., one on an uppermost die 925A or 935A of the corresponding stack of HBM 920 or 930). Further, in some embodiments, only a subset of the HBMs 920-930 and 1020-1030 includes one or more die crack monitors 1051-1054.

One or more of the HBMs 920-930 and 1020-1030 may include a MISR. The HBM stores a value in the MISR based on multiple inputs received by the HBM.

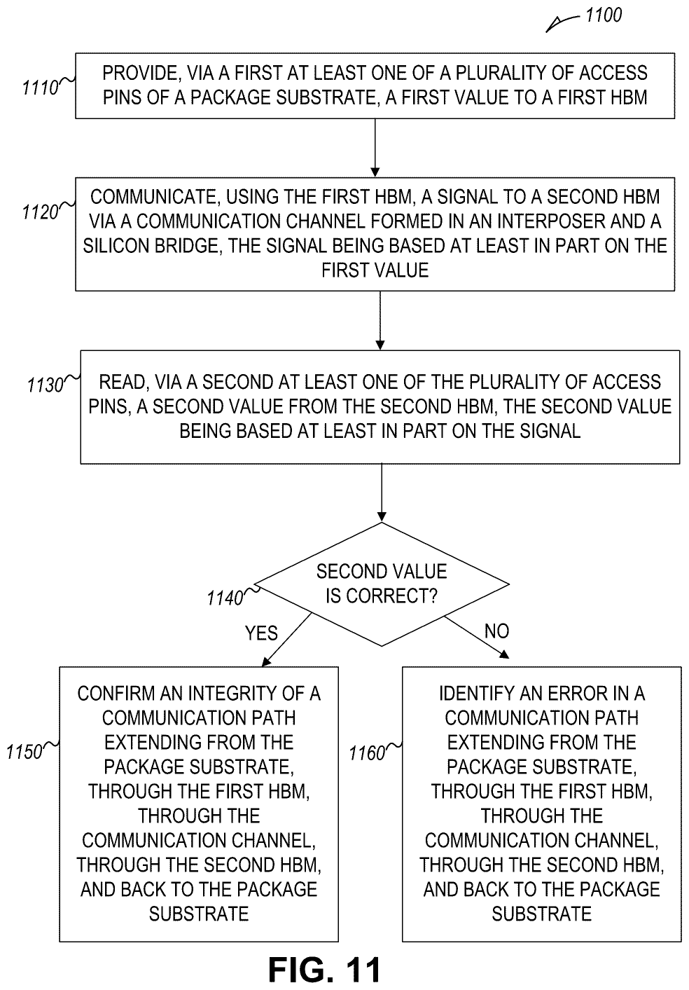

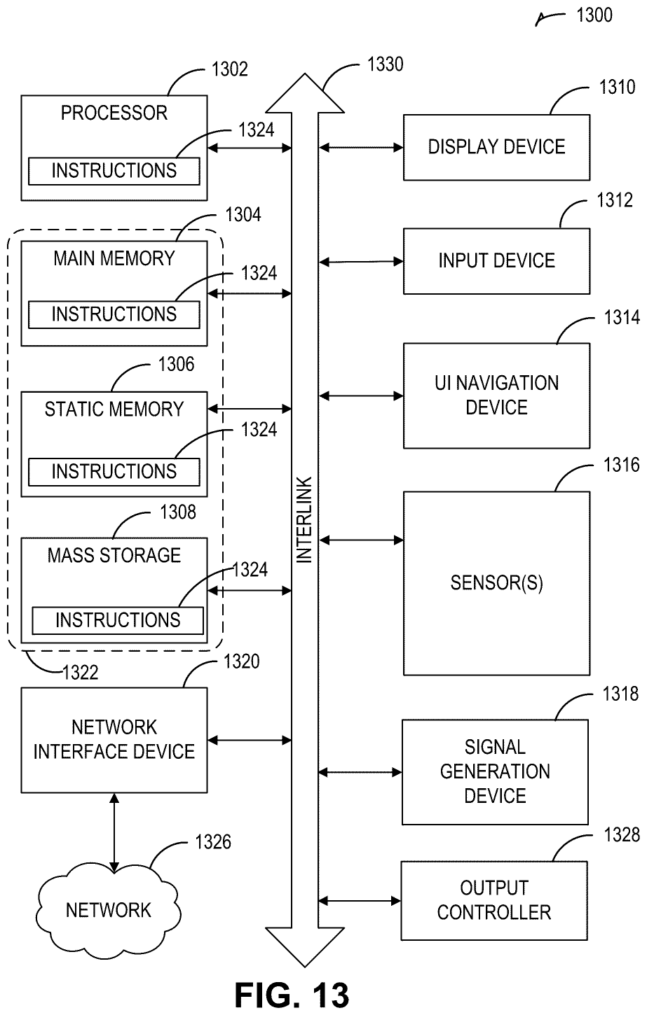

FIG. 11 illustrates a flowchart of a method 1100 for testing a SiP, according to some example embodiments. By way of example and not limitation, the method 1100 may be performed by a host device coupled to one or more access pins of a SiP (e.g., one of the SiPs of FIGS. 1-10). The host device may be implemented by a computing device of the form of the example machine 1300 of FIG. 13.

In operation 1110, the host device provides, via a first at least one of a plurality of access pins of a package substrate, a first value to a first HBM. For example, an 8-bit value may be provided using a single access pin by changing the logical input value over time. As another example, a multi-bit value may be provided using multiple pins, with each pin receiving one bit of the multi-bit value simultaneously. Additional access pins may be used for control signals, error correction, and so on.

The host device communicates, using the first HBM, a signal to a second HBM via a communication channel formed in an interposer and a silicon bridge, the signal being based at least in part on the first value (operation 1120). The SiPs of FIGS. 7-10 show such a communication path. The signal may communicate the first value itself, a function of the first value (e.g., a 2's complement of the first value), data identified by the first value (e.g., data stored in the first HBM at a location determined by using the first value as an address), or any suitable combination thereof. For example, the signal may communicate the first value and a checksum bit, which is a function of the first value.

In operation 1130, the host device reads, via a second at least one of the plurality of access pins, a second value from the second HBM, the second value being based at least in part on the signal. As described above with respect to operation 1110, various signaling methods may be used to communicate the second value. As described above with respect to operation 1120, the second value may be equal to a value communicated by the signal, a function of a value communicated by the signal, data identified by the value communicated by the signal, or any suitable combination thereof.

The host device determines, in operation 1140, if the second value is correct. For example, if the communications in operations 1120 and 1130 attempt to transmit the first value without modification, the host device can determine if the second value is correct by comparing the second value to the first value.

If the second value is determined to be correct, the method 1100 continues with operation 1150. In operation 1150, the host device confirms an integrity of a communication path extending from the package substrate, through the first HBM, through the communication channel, through the second HBM, and back to the package substrate. For example, the confirmation may be written to a log file, stored in a database, presented on a screen of the host device, or presented using an indicator (e.g., a green light-emitting diode) of the host device.

If the second value is determined to be incorrect, the method 1100 continues with operation 1160. In operation 1160, the host device identifies an error in a communication path extending from the package substrate, through the first HBM, through the communication channel, through the second HBM, and back to the package substrate. For example, the error may be written to a log file, stored in a database, presented on a screen of the host device, or presented using an indicator (e.g., a red light-emitting diode) of the host device.

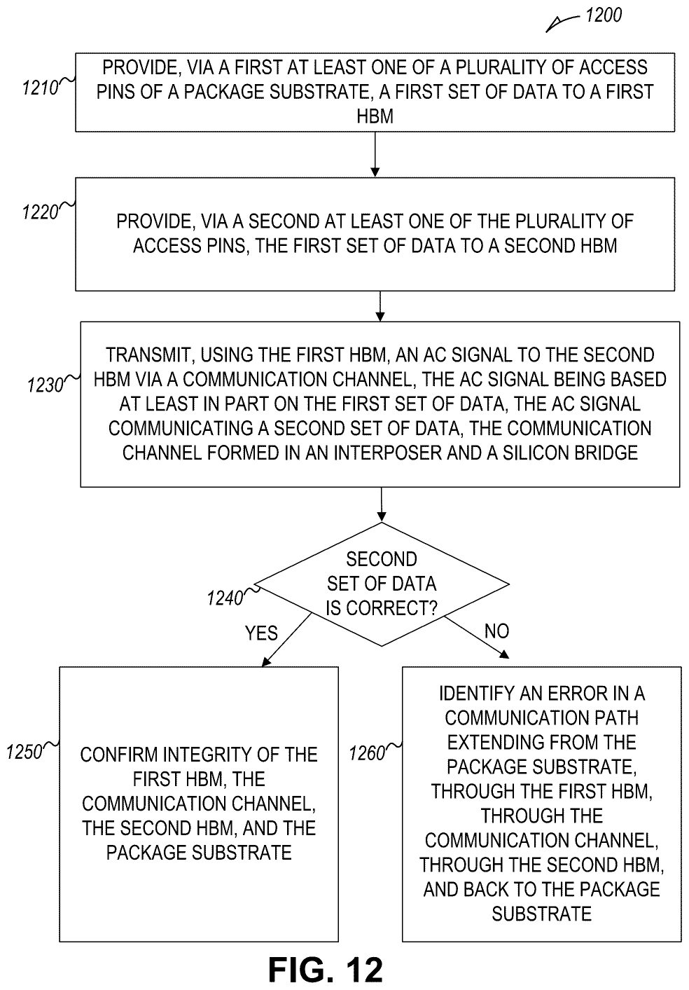

FIG. 12 illustrates a flowchart of a method 1200 for testing a SiP, according to some example embodiments. By way of example and not limitation, the method 1200 may be performed by a host device coupled to one or more access pins of a SiP (e.g., one of the SiPs of FIGS. 1-10). The host device may be implemented by a computing device of the form of the example machine 1300 of FIG. 13.

In operation 1210, the host device provides, via a first at least one of a plurality of access pins of a package substrate, a first set of data to a first HBM. For example, kilobytes or megabytes of predetermined data may be provided to the HBM to populate the memory storage of the first HBM.

The host device provides, via a second at least one of the plurality of access pins, the first set of data to a second HBM (operation 1220). Thus, after operations 1210 and 1220, both HBMs have received the same set of data.

The host device causes the first HBM to transmit an AC signal to the second HBM via a communication channel formed in an interposer and a silicon bridge. The AC signal is based at least in part on the first set of data and communicates a second set of data (operation 1230). The signal may communicate the first set of data, a function of the first set of data (e.g., a checksum of the first data), or any suitable combination thereof. For example, the first HBM may calculate a first MISR value based at least in part on the first set of data and transmit the first MISR value to the second HBM via the communication channel.

In operation 1240, the second HBM determines if the second set of data is correct. For example, if the AC signal in operation 1230 attempts to transmit the first set of data without modification, the second HBM can determine if the second set of data is correct by comparing the second set of data to the first set of data. As another example, if the AC signal attempts to transmit a checksum, hash, or second MISR value of the first set of data, the second HBM can compute the checksum, hash, or second MISR value from the first set of data and compare the result with the received value. A mismatch in the calculated value with the received value (e.g., a mismatch between the first MISR value and the second MISR value) indicates that the integrity of the first HBM or the second HBM has been compromised. The second HBM may communicate whether the second data is correct with the host device via the second at least one of the plurality of access pins.

If the second set of data is determined to be correct, the method 1200 continues with operation 1250. In operation 1250, the host device confirms the integrity of the first HBM, the communication channel, the second HBM, and the package substrate. For example, the confirmation may be written to a log file, stored in a database, presented on a screen of the host device, or presented using an indicator (e.g., a green light-emitting diode) of the host device.

If the second set of data is determined to be incorrect, the method 1200 continues with operation 1260. In operation 1260, the host device identifies an error in a communication path extending from the package substrate, through the first HBM, through the communication channel, through the second HBM, and back to the package substrate. For example, the error may be written to a log file, stored in a database, presented on a screen of the host device, or presented using an indicator (e.g., a red light-emitting diode) of the host device.

Thus, by use of the methods 1100 and 1200, structural integrity in a SiP (or the lack thereof) can be determined. To better illustrate the SiP devices and test methods for SiP devices discussed herein, a non-limiting set of Example embodiments are set forth below as numerically identified Examples.

Example 1 is a proxy device for use with integration bringup processes for a system-in-package (SiP) device, the SiP device comprising a plurality of high-bandwidth memories (HBMs) and a system on a chip (SOC), the proxy device comprising: a base substrate; the plurality of HBMs carried by the base substrate, wherein the plurality of HBMs include, a first HBM and a second HBM; a silicon bridge carried by the base substrate, the silicon bridge having a same size and shape as the SOC; and a communication channel formed in the base substrate and the silicon bridge, the communication channel communicatively coupling the first HBM to the second HBM.

In Example 2, the subject matter of Example 1, wherein: the first HBM is configured to: receive a first value via a first access pin of the base substrate; and based on the first value, communicate a signal to the second HBM via the communication channel; and the second HBM is configured to provide, based on the signal, a second value via a second access pin of the base substrate.

In Example 3, the subject matter of Examples 1-2, wherein: the first HBM is configured to: receive a first value via a first access pin of the base substrate; and based on the first value, communicate an alternating current (AC) signal to the second HBM via the communication channel; and the second HBM is configured to provide, based on the AC signal, a second value via a second access pin of the base substrate.

In Example 4, the subject matter of Examples 1-3, wherein: the first HBM is configured to receive a first value via a first access pin of the base substrate; the second HBM is configured to receive a second value via a second access pin of the base substrate; the first HBM is configured to transmit a signal, based on the first value, to the second HBM; and the second HBM is configured to determine, based on the signal and the second value, whether an error exists in the proxy device.

In Example 5, the subject matter of Examples 1-4, wherein: the plurality of HBMs further includes a third HBM; the communication channel is a first communication channel; and the proxy device further comprises a second communication channel formed in the base substrate and the silicon bridge, the second communication channel communicatively coupling the first HBM to the third HBM.

In Example 6, the subject matter of Examples 1-5, wherein the first HBM includes front-end-of-line (FEOL) or middle-of-line (MOL) layers.

In Example 7, the subject matter of Examples 1-6, wherein the first HBM and the second HBM include respective active circuits and the silicon bridge does not include an active circuit.

In Example 8, the subject matter of Examples 1-7 includes a die crack monitor circuit positioned at least partially around a perimeter of the first HBM.

In Example 9, the subject matter of Examples 1-8, wherein the first HBM comprises a multiple input signature register (MISR).

Example 10 is a method for testing compatibility of a system-in-package (SiP) device with a package substrate, the SiP device comprising a plurality of high-bandwidth memories (HBMs) and a system on a chip (SOC), the method comprising: forming a device as a proxy for the SiP device, wherein forming the device includes, integrating a first HBM, a second HBM, and a silicon bridge with an interposer, the silicon bridge having a same size and shape as the SOC, wherein the integrating includes coupling each of the first and second HBMs to a communication channel formed in the interposer and the silicon bridge to communicably couple the first HBM to the second HBM; integrating the device with the package substrate, wherein integrating the device with the package substrate includes communicably coupling the first and second HBMs to two or more access pins of the package substrate; coupling an external testing device to the two or more access pins; and executing, using the external testing device, one or more tests on the first and second HBMs.

In Example 11, the subject matter of Example 10, wherein executing the one or more tests includes: providing, via at least one of the two or more access pins, a first value to the first HBM; communicating, using the first HBM, a signal to the second HBM via the communication channel, wherein the signal is based at least in part on the first value; reading, via an access pin of the two or more access pins, a second value from the second HBM, wherein the second value is based at least in part on the signal; determining that the second value is correct; and based at least in part on the determination, confirming integrity of a communication path extending from the package substrate, through the first HBM, through the communication channel, through the second HBM, and back to the package substrate.

In Example 12, the subject matter of Examples 10-11, wherein executing the one or more tests includes: providing, via at least one of the two or more access pins, a first value to the first HBM; communicating, using the first HBM, a signal to the second HBM via the communication channel, wherein the signal is based at least in part on the first value; reading, via an access pin of the two or more access pins, a second value from the second HBM, wherein the second value is based at least in part on the signal; determining that the second value is incorrect; and based at least in part on the determination, identifying an error in a communication path extending from the package substrate, through the first HBM, through the communication channel, through the second HBM, and back to the package substrate.

In Example 13, the subject matter of Examples 10-12, wherein executing the one or more tests includes: providing, via at least one of the two or more access pins, a first set of data to the first HBM; providing, via an access pin of the two or more access pins, the first set of data to the second HBM; transmitting, using the first HBM, an alternating current (AC) signal to the second HBM via the communication channel, wherein the AC signal is based at least in part on the first set of data and communicates a second set of data; determining, at the second HBM, that the second set of data is correct; and based at least in part on the determination, confirming integrity of the first HBM, the communication channel, and the second HBM.

In Example 14, the subject matter of Examples 10-13, wherein executing the one or more tests includes: providing, via at least one of the two or more access pins, a first set of data to the first HBM; providing, via an access pin of the two or more access pins, the first set of data to the second HBM; transmitting, using the first HBM, an alternating current (AC) signal to the second HBM via the communication channel, wherein the AC signal is based at least in part on the first set of data and communicates a second set of data; determining, at the second HBM, that the second set of data is incorrect; and based at least in part on the determination, identifying an error in the first HBM, the communication channel, or the second HBM.

In Example 15, the subject matter of Examples 10-14, wherein executing the one or more tests includes checking, using a die crack sensor, for cracks resulting from integration of the device with the package substrate.

In Example 16, the subject matter of Examples 10-15, wherein: the communication channel is a first communication channel; forming the device further includes integrating a third HBM and a fourth HBM with the interposer, wherein integrating the third and fourth HBMs with the interposer includes coupling each of the third and fourth HBMs to a second communication channel formed in the interposer and the silicon bridge to communicably couple the third HBM to the fourth HBM; and executing the one or more tests includes executing a first subset of the one or more tests on the first and second HBMs and a second subset of the one or more tests on the third and fourth HBMs.

In Example 17, the subject matter of Example 16, wherein the integrating of the first and third HBMs with the interposer further includes coupling each of the first and third HBMs to a third communication channel formed in the interposer to communicably couple the first HBM to the third HBM.

In Example 18, the subject matter of Examples 10-17, wherein each of the first and second HBMs includes a stack of substrates, and wherein at least one substrate in each stack includes front-end-of-line (FEOL) or middle-of-line (MOL) layers.

In Example 19, the subject matter of Examples 10-18, wherein the executing of the one or more tests includes: receiving a first set of data at the first HBM; calculating, at the first HBM, a first multiple input signature register (MISR) value based at least in part on the first set of data; transmitting the first MISR value to the second HBM via the communication channel; receiving, at the second HBM, a second set of data; calculating, at the second HBM, a second MISR value based at least in part on the second set of data; and comparing the first MISR value to the second MISR value, wherein a mismatch between the first MISR value and the second MISR value indicates integrity of the first HBM or the second HBM has been compromised.

In Example 20, the subject matter of Examples 10-19, wherein the executing of the one or more tests includes detecting cracks in one or more dies of at least one of the plurality of HBMs.

Example 21 is an apparatus comprising means to implement any of Examples 1-20.

FIG. 13 illustrates a block diagram of an example machine 1300 with which, in which, or by which any one or more of the techniques (e.g., methodologies, such as including SiP testing methodologies) discussed herein can be implemented. The example machine 1300 may be used as a host device for testing a SiP. Additionally, components of the example machine 1300 may have been developed using SiP testing.

Examples, as described herein, can include, or can operate by, logic or a number of components, or mechanisms in the machine 1300. Circuitry (e.g., processing circuitry) is a collection of circuits implemented in tangible entities of the machine 1300 that include hardware (e.g., simple circuits, gates, logic, etc.). Circuitry membership can be flexible over time. Circuitries include members that can, alone or in combination, perform specified operations when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time. Additional examples of these components with respect to the machine 1300.

In alternative embodiments, the machine 1300 can operate as a standalone device or can be connected (e.g., networked) to other machines. In a networked deployment, the machine 1300 can operate in the capacity of a server machine, a client machine, or both in server-client network environments. In an example, the machine 1300 can act as a peer machine in peer-to-peer (P2P) (or other distributed) network environment. The machine 1300 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 1300 (e.g., computer system) can include a hardware processor 1302 (e.g., a central processing unit (CPU), a graphics processing unit (GPU), a hardware processor core, or any combination thereof), a main memory 1304, a static memory 1306 (e.g., memory or storage for firmware, microcode, a basic-input-output (BIOS), unified extensible firmware interface (UEFI), etc.), one or more high-bandwidth memories or other devices comprising one or more high-bandwidth memories, and mass storage device 1308 (e.g., hard drives, tape drives, flash storage, or other block devices) some or all of which can communicate with each other via an interlink 1330 (e.g., bus). The machine 1300 can further include a display device 1310, an alphanumeric input device 1312 (e.g., a keyboard), and a user interface (UI) navigation device 1314 (e.g., a mouse). In an example, the display device 1310, the input device 1312, and the UI navigation device 1314 can be a touch screen display. The machine 1300 can additionally include a signal generation device 1318 (e.g., a speaker), a network interface device 1320, and one or more sensor(s) 1316, such as a global positioning system (GPS) sensor, compass, accelerometer, or other sensor. The machine 1300 can include an output controller 1328, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 1302, the main memory 1304, the static memory 1306, or the mass storage device 1308 can be, or include, a machine-readable media 1322 on which is stored one or more sets of data structures or instructions 1324 (e.g., software) embodying or used by any one or more of the techniques or functions described herein. The instructions 1324 can also reside, completely or at least partially, within any of registers of the hardware processor 1302, the main memory 1304, the static memory 1306, or the mass storage device 1308 during execution thereof by the machine 1300. In an example, one or any combination of the hardware processor 1302, the main memory 1304, the static memory 1306, or the mass storage device 1308 can constitute the machine-readable media 1322. While the machine-readable media 1322 is illustrated as a single medium, the term “machine-readable medium” can include a single medium or multiple media (e.g., a centralized or distributed database, or associated caches and servers) configured to store the one or more instructions 1324.

The term “machine readable medium” can include any medium that is capable of storing, encoding, or carrying instructions for execution by the machine 1300 and that cause the machine 1300 to perform any one or more of the techniques of the present disclosure, or that is capable of storing, encoding, or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on the machine-readable media 1322 can be representative of the instructions 1324, such as instructions 1324 themselves or a format from which the instructions 1324 can be derived. This format from which the instructions 1324 can be derived can include source code, encoded instructions (e.g., in compressed or encrypted form), packaged instructions (e.g., split into multiple packages), or the like. The information representative of the instructions 1324 in the machine-readable media 1322 can be processed by processing circuitry into the instructions to implement any of the operations discussed herein. For example, deriving the instructions 1324 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 1324.

In an example, the derivation of the instructions 1324 can include assembly, compilation, or interpretation of the information (e.g., by the processing circuitry) to create the instructions 1324 from some intermediate or preprocessed format provided by the machine-readable media 1322. The information, when provided in multiple parts, can be combined, unpacked, and modified to create the instructions 1324. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, compiled or interpreted (e.g., into a library, stand-alone executable etc.) at a local machine, and executed by the local machine.

The instructions 1324 can be further transmitted or received over a communications network 1326 using a transmission medium via the network interface device 1320 utilizing any one of a number of transfer protocols (e.g., frame relay, internet protocol, transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1320 can include one or more physical jacks (e.g., Ethernet, coaxial, or phone jacks) or one or more antennas to connect to the network 1326. In an example, the network interface device 1320 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1300, and includes digital or analog communications signals or other intangible medium to facilitate communication of such software. A transmission medium is a machine readable medium.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A proxy device for use with integration bringup processes for a system-in-package (SiP) device, the SiP device comprising a plurality of high-bandwidth memories (HBMs) and a system on a chip (SOC), the proxy device comprising:
a base substrate;
the plurality of HBMs carried by the base substrate, wherein the plurality of HBMs include a first HBM and a second HBM;
a silicon bridge carried by the base substrate, the silicon bridge having a same size and shape as the SOC; and
a communication channel formed in the base substrate and the silicon bridge, the communication channel communicatively coupling the first HBM to the second HBM.

2. The proxy device of claim 1, wherein:
the first HBM is configured to:
receive a first value via a first access pin of the base substrate; and
based on the first value, communicate a signal to the second HBM via the communication channel; and
the second HBM is configured to provide, based on the signal, a second value via a second access pin of the base substrate.

3. The proxy device of claim 1, wherein:
the first HBM is configured to:
receive a first value via a first access pin of the base substrate; and
based on the first value, communicate an alternating current (AC) signal to the second HBM via the communication channel; and
the second HBM is configured to provide, based on the AC signal, a second value via a second access pin of the base substrate.

4. The proxy device of claim 1, wherein:
the first HBM is configured to receive a first value via a first access pin of the base substrate;
the second HBM is configured to receive a second value via a second access pin of the base substrate;
the first HBM is configured to transmit a signal, based on the first value, to the second HBM; and
the second HBM is configured to determine, based on the signal and the second value, whether an error exists in the proxy device.

5. The proxy device of claim 1, wherein:
the plurality of HBMs further includes a third HBM;
the communication channel is a first communication channel; and
the proxy device further comprises a second communication channel formed in the base substrate and the silicon bridge, the second communication channel communicatively coupling the first HBM to the third HBM.

6. The proxy device of claim 1, wherein the first HBM includes front-end-of-line (FEOL) or middle-of-line (MOL) layers.

7. The proxy device of claim 1, wherein the first HBM and the second HBM include respective active circuits and the silicon bridge does not include an active circuit.

8. The proxy device of claim 1, further comprising a die crack monitor circuit positioned at least partially around a perimeter of the first HBM.

9. The proxy device of claim 1, wherein the first HBM comprises a multiple input signature register (MISR).

10. A method for testing compatibility of a system-in-package (SiP) device with a package substrate, the SiP device comprising a plurality of high-bandwidth memories (HBMs) and a system on a chip (SOC), the method comprising:
forming a device as a proxy for the SiP device, wherein forming the device includes integrating a first HBM, a second HBM, and a silicon bridge with an interposer, the silicon bridge having a same size and shape as the SOC, wherein the integrating includes coupling each of the first and second HBMs to a communication channel formed in the interposer and the silicon bridge to communicably couple the first HBM to the second HBM;
integrating the device with the package substrate, wherein integrating the device with the package substrate includes communicably coupling the first and second HBMs to two or more access pins of the package substrate;
coupling an external testing device to the two or more access pins; and
executing, using the external testing device, one or more tests on the first and second HBMs.

11. The method of claim 10, wherein executing the one or more tests includes:
providing, via at least one of the two or more access pins, a first value to the first HBM;
communicating, using the first HBM, a signal to the second HBM via the communication channel, wherein the signal is based at least in part on the first value;
reading, via an access pin of the two or more access pins, a second value from the second HBM, wherein the second value is based at least in part on the signal;
determining that the second value is correct; and
based at least in part on the determination, confirming integrity of a communication path extending from the package substrate, through the first HBM, through the communication channel, through the second HBM, and back to the package substrate.

12. The method of claim 10, wherein executing the one or more tests includes:
providing, via at least one of the two or more access pins, a first value to the first HBM;
communicating, using the first HBM, a signal to the second HBM via the communication channel, wherein the signal is based at least in part on the first value;
reading, via an access pin of the two or more access pins, a second value from the second HBM, wherein the second value is based at least in part on the signal;
determining that the second value is incorrect; and
based at least in part on the determination, identifying an error in a communication path extending from the package substrate, through the first HBM, through the communication channel, through the second HBM, and back to the package substrate.

13. The method of claim 10, wherein executing the one or more tests includes:
providing, via at least one of the two or more access pins, a first set of data to the first HBM;
providing, via an access pin of the two or more access pins, the first set of data to the second HBM;
transmitting, using the first HBM, an alternating current (AC) signal to the second HBM via the communication channel, wherein the AC signal is based at least in part on the first set of data and communicates a second set of data;
determining, at the second HBM, that the second set of data is correct; and
based at least in part on the determination, confirming integrity of the first HBM, the communication channel, and the second HBM.

14. The method of claim 10, wherein executing the one or more tests includes:
providing, via at least one of the two or more access pins, a first set of data to the first HBM;
providing, via an access pin of the two or more access pins, the first set of data to the second HBM;
transmitting, using the first HBM, an alternating current (AC) signal to the second HBM via the communication channel, wherein the AC signal is based at least in part on the first set of data and communicates a second set of data;
determining, at the second HBM, that the second set of data is incorrect; and
based at least in part on the determination, identifying an error in the first HBM, the communication channel, or the second HBM.

15. The method of claim 10, wherein executing the one or more tests includes checking, using a die crack sensor, for cracks resulting from integration of the device with the package substrate.

16. The method of claim 10, wherein:
the communication channel is a first communication channel;
forming the device further includes integrating a third HBM and a fourth HBM with the interposer, wherein integrating the third and fourth HBMs with the interposer includes coupling each of the third and fourth HBMs to a second communication channel formed in the interposer and the silicon bridge to communicably couple the third HBM to the fourth HBM; and
executing the one or more tests includes executing a first subset of the one or more tests on the first and second HBMs and a second subset of the one or more tests on the third and fourth HBMs.

17. The method of claim 16, wherein the integrating of the first and third HBMs with the interposer further includes coupling each of the first and third HBMs to a third communication channel formed in the interposer to communicably couple the first HBM to the third HBM.

18. The method of claim 10, wherein each of the first and second HBMs includes a stack of substrates, and wherein at least one substrate in each stack includes front-end-of-line (FEOL) or middle-of-line (MOL) layers.

19. The method of claim 10, wherein the executing of the one or more tests includes:
receiving a first set of data at the first HBM;
calculating, at the first HBM, a first multiple input signature register (MISR) value based at least in part on the first set of data;
transmitting the first MISR value to the second HBM via the communication channel;
receiving, at the second HBM, a second set of data;
calculating, at the second HBM, a second MISR value based at least in part on the second set of data; and
comparing the first MISR value to the second MISR value, wherein a mismatch between the first MISR value and the second MISR value indicates integrity of the first HBM or the second HBM has been compromised.

20. The method of claim 10, wherein the executing of the one or more tests includes detecting cracks in one or more dies of at least one of the plurality of HBMs.
